(19) United States
(12) Patent Application Publication
(10) Pub. No.: US 2013/0163289 A1
(43) Pub. Date: Jun. 27, 2013

(54) POWER SWITCHING DRIVING APPARATUS, AND POWER FACTOR CORRECTION DEVICE AND POWER SUPPLY DEVICE HAVING THE SAME

(71) Applicants: Myeung Su KIM, Suwon (KR); Koon Shik CHO, Seoul (KR); Jae Hyung LEE, Suwon (KR); Kwang Mook LEE, Suwon (KR)

(72) Inventors: Myeung Su KIM, Suwon (KR); Koon Shik CHO, Seoul (KR); Jae Hyung LEE, Suwon (KR); Kwang Mook LEE, Suwon (KR)

(73) Assignee: SAMSUNG ELECTRO-MECHANICS CO., LTD.

(21) Appl. No.: 13/405,791

(22) Filed: Feb. 27, 2012

(30) Foreign Application Priority Data
Dec. 23, 2011 (KR) 10-2011-0141634

(51) Int. Cl. H03K 3/36; G05F 1/46; H02M 3/335

(52) U.S. Cl. 363/20; 327/109; 323/282

(57) ABSTRACT

There are provided a power switching driving apparatus able to reduce a circuit area and increase a driving speed, and a power factor correction device and a power supply device having the same. The power switching driving apparatus includes: a first driving unit providing a switching signal in response to a control signal from the outside; a second driving unit including first and second NMOS FETs cascode-connected between an operational power source terminal supplying pre-set operation power and a ground, and performing switching complimentarily in response to the switching signal to provide a switching control signal controlling power switching; a current supply unit supplying a current for driving the second driving unit; and a voltage maintaining unit maintaining a voltage for driving the second driving unit.

### CROSS-REFERENCE TO RELATED APPLICATIONS

This application claims the priority of Korean Patent Application No. 10-2011-0141634 filed on Dec. 23, 2011, in the Korean Intellectual Property Office, the disclosure of which is incorporated herein by reference.

### BACKGROUND OF THE INVENTION

1. Field of the Invention

The present invention relates to a power switching driving apparatus having a reduced circuit area and a fast driving speed, and a power factor correction device and power supply device having the same.

2. Description of the Related Art

In general, electronic devices devised for meeting users' various demands employ an external or internal power device.

Meanwhile, users' demands for effectively using energy may also be in connection with such electronic devices. In particular, electronic devices exported to the USA, Europe, and the like, should satisfy efficiency characteristics stipulated in each country.

Thus, the structures of power devices supplying power to electronic devices employ a switching mode power supply circuit. In order to turn a power switch of a switching mode power supply circuit on or off, a power switching driving apparatus is required.

In order to switch large capacity power, driving capacity of a power switch is increased and a current capacity able to be handled by the power switching driving apparatus is also increased, resulting in a defect in which a circuit area of the power switching driving apparatus is increased.

Namely, in order to control power switching, the power switching driving apparatus is used by cascade-connecting a P-type channel metal oxide semiconductor (PMOS) transistor and an N-type channel metal oxide semiconductor (NMOS) transistor to each other, and here, since gate capacitors of the transistors are relatively very large, a great amount of current should be drained for a fast operation, and accordingly, a circuit area is increased.

### SUMMARY OF THE INVENTION

An aspect of the present invention provides a power switching driving apparatus in which two NMOS transistors are cascade connected to control power switching, thereby reducing a circuit area and increasing a driving speed, a power factor correction device and a power supply device having the same.

According to an aspect of the present invention, there is provided a power switching driving apparatus including: a first driving unit providing a switching signal in response to a control signal from the outside; a second driving unit including a first NMOS FET and a second NMOS FET cascode-connected between an operational power source terminal supplying pre-set operation power and a ground, and performing switching complimentarily in response to the switching signal to provide a switching control signal for controlling power switching; a current supply unit supplying a current required for driving the second driving unit; and a voltage maintaining unit maintaining a voltage required for driving the second driving unit.

The first driving unit may include a switching element switched according to the control signal.

The second NMOS FET may be switched on and off according to switching ON and OFF operation of the switching element and the first NMOS FET may be complementarily switched on and off with the second NMOS FET to provide the switching control signal.

The current supply unit may include: a current source supplying a pre-set current; and a current mirror unit including first and second PMOS FETs cascode-connected between the operational power source terminal and the current source, and third and fourth PMOS FETs connected in parallel to the first and second PMOS FETs and cascode-connected between the operational power source terminal and the second NMOS FET, and mirroring a current from the current source to the second NMOS FET.

The voltage maintaining unit may include at least one Zener diode connected between a gate of the second NMOS FET and the ground.

The switching element may be a switching NMOS FET.

According to another aspect of the present invention, there is provided a power factor correction device including: a power factor correction unit correcting a power factor by switching rectified power in response to a switching control signal; and a power switching driving apparatus including a first driving unit providing a switching signal in response to a control signal from the outside and a second driving unit including a first NMOS FET and a second NMOS FET cascode-connected between an operational power source terminal supplying pre-set operation power and a ground, and performing switching complimentarily according to the switching signal to provide the switching control signal.

The power switching driving apparatus may further include: a current supply unit supplying a current required for driving the second driving unit; and a voltage maintaining unit maintaining a voltage required for driving the second driving unit.

According to another aspect of the present invention, there is provided a power supply device including: a power conversion unit switching input power in response to a switching control signal to output pre-set driving power; and a power switching driving apparatus including a first driving unit providing a switching signal in response to a control signal from the outside, and a second driving unit including a first NMOS FET and a second NMOS FET cascode-connected between an operational power source terminal supplying pre-set operation power and a ground and performing switching complimentarily according to the switching signal to provide the switching control signal.

The power supply device may further include: a power factor correction unit switching rectified power, correcting a power factor thereof, and providing the same to the power conversion unit.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic block diagram of a power switching driving apparatus according to an embodiment of the present invention;

FIG. 2 is a detailed circuit diagram of the power switching driving apparatus according to an embodiment of the present invention;

FIG. 3 is a schematic circuit diagram of a power factor correction device employing the power switching driving apparatus according to an embodiment of the present invention;

FIG. 4 is a schematic circuit diagram of a power supply device employing the power switching driving apparatus according to an embodiment of the present invention;

FIG. 5 is graphs showing simulation waveforms of a control signal and a switching control signal of the power switching driving apparatus according to an embodiment of the present invention; and

FIG. 6 is a graph showing a simulation waveform of a switching control signal over a change in an operation power voltage of the power switching driving apparatus according to an embodiment of the present invention.

### DETAILED DESCRIPTION OF THE EMBODIMENTS

Hereinafter, embodiments will be described in detail with reference to the accompanying drawings so that they can be easily practiced by those skilled in the art to which the present invention pertains.

However, in describing embodiments of the present invention, detailed descriptions of well-known functions or constructions will be omitted so as not to obscure the gist of the present invention.

In addition, like or similar reference numerals denote parts performing similar functions and actions throughout the drawings.

A case in which anyone part is connected with the other part includes a case in which the parts are directly connected with each other and a case in which the parts are indirectly connected with each other with other elements interposed therebetween.

In addition, unless explicitly described otherwise, “comprising” any components will be understood to imply the inclusion of other components but not the exclusion of any other components.

Embodiments of the present invention will now be described in detail with reference to the accompanying drawings.

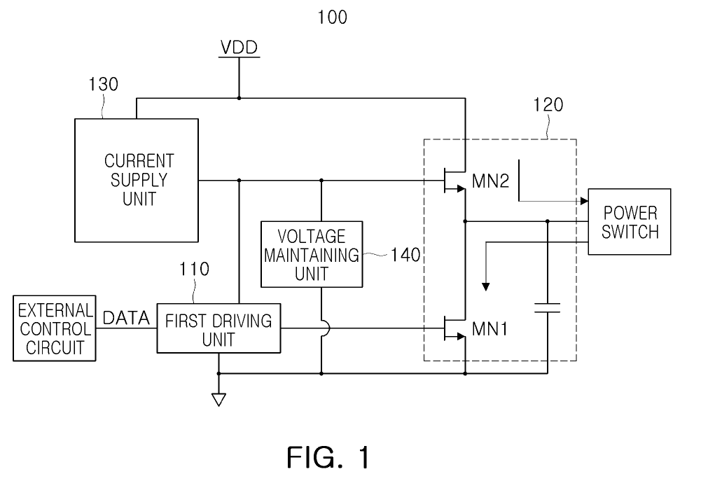

FIG. 1 is a schematic block diagram of a power switching driving apparatus according to an embodiment of the present invention.

With reference to FIG. 1, a power switching driving apparatus 100 may include a first driving unit 110, a second driving unit 120, a current supply unit 130, and a voltage maintaining unit 140.

The first driving unit 110 may provide a switching signal in response to a control signal DATA from the outside. The second driving unit 120 may include two NMOS FETs MN1 and MN2 cascode-connected between an operational power source terminal providing pre-set operation power VDD and a ground, and may perform switching in response to the switching signal from the first driving unit 110 to provide a switching control signal controlling power switching.

The current supply unit 130 may supply a current required for providing the switching control signal of the second driving unit 120. The voltage maintaining unit 140 may maintain a voltage level required for a gate of the second NMOS FET MN2 of the second driving unit 120.

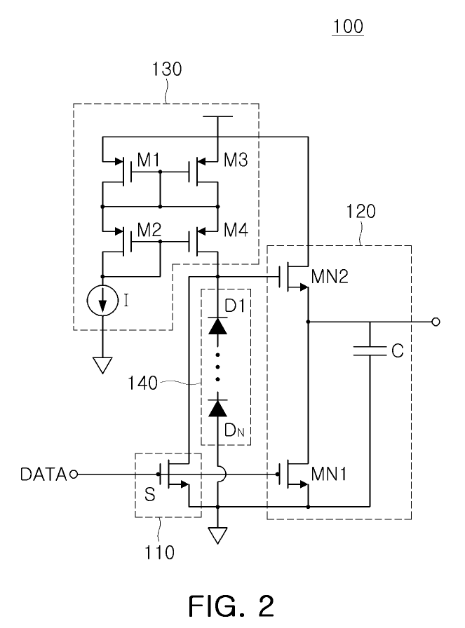

FIG. 2 is a detailed circuit diagram of the power switching driving apparatus according to an embodiment of the present invention.

With reference to FIGS. 1 and 2, the first driving unit 110 of the power switching driving apparatus 100 according to an embodiment of the present invention may include at least one switching NMOS FET(S).

The control signal DATA from the outside may be input to a gate of the switching NMOS FET (S), a drain of the switching NMOS FET (S) may be connected to a gate of the second NMOS FET MN2 of the second driving unit 120, and a source of the switching NMOS FET(S) may be connected to a ground.

The first and second NMOS FETs MN1 and MN2 of the second driving unit 120 may be cascode-connected between the operational power source terminal and the ground. In detail, in the similar manner to the gate of the switching NMOS FET (S), the control signal DATA from the outside may be input to a gate of the first NMOS FET MN1, a source of the first NMOS FET MN1 may be connected to the ground, and a drain of the first NMOS FET MN1 may be connected to a source of the second NMOS FET MN2.

A gate of the second NMOS FET MN2 may be connected with the drain of the switching NMOS FET (S) and the current supply unit 130, and a drain of the second NMOS FET MN2 may be connected to the operational power source terminal.

According to the foregoing electrical connection, when the control signal DATA is a high level signal, the switching NMOS FET (S) and the first NMOS FET MN1 are switched on and the second NMOS FET MN2 is switched off, so power applied to a switching element is bypassed to the ground. Thus, the switching control signal transmitted to the switching element may become a low level signal to switch off the switching element.

When the control signal DATA is a low level signal, the switching NMOS FET (S) and the first NMOS FET MN1 are switched off and the second NMOS FET MN2 is switched on to apply power of a pre-set level to the switching element. Accordingly, the switching control signal transmitted to the switching element becomes a high level signal to switch on the switching element. To this end, the voltage maintaining unit 140 may maintain a voltage level applied to the second NMOS FET MN2.

The voltage maintaining unit 140 may include at least one Zener diode, or may include a plurality of Zener diodes D1 to DN according to a voltage level needed to be maintained. The voltage maintaining unit 140 may maintain voltage applied to the gate of the second NMOS FET MN2 to allow the second NMOS FET MN2 to perform a switching ON operation. Namely, a voltage between the gate and the source of the second NMOS FET MN2 may be uniformly maintained to reduce a change in a drain current. When a switching control signal applied to the switching element has a high level, a voltage level may be uniformly maintained regardless of a power source voltage and a drain current of the switching element may also be uniformly maintained. In addition, the NMOS FET may have a smaller circuit area than that of a PMOS FET, with respect to an identical drain current. In order to maintain the voltage of the voltage maintaining unit 140, the current supply unit 130 may be employed.

The current supply unit 130 may include a current mirror unit comprised of first to fourth PMOS FETs which are cascode-connected to a current source I.

The current source I may supply a current of a pre-set level, and the current mirror unit may mirror the current from the current source I to transfer the same to the gate of the second NMOS FET MN2.

To this end, the first and second PMOS FETs M1 and M2 may be cascode-connected between the operational power source terminal of the current mirror unit and the current source I, and third and fourth PMOS FETs M3 and M4 may be cascode-connected between the operational power source terminal and the voltage maintaining unit 140. In order to mirror a current, the first and second cascode-connected PMOS FETs M1 and M2 and the third and fourth cascode-connected PMOS FETs M3 and M4 may be connected in parallel, gates of the first PMOS FET M1 and the third PMOS FET M3 may be connected to each other, gates of the second PMOS FET M2 and the fourth PMOS FET M4 may be connected to each other, the gate and a drain of the first PMOS FET M1 may be connected, and the gate and a drain of the second PMOS FET M2 may be connected.

The Zener diode of the voltage maintaining unit 140 may generate a Zener voltage according to the current supplied from the current source I. Namely, unless an inverse current is present, the Zener diode may maintain a ‘0’ voltage, and when a current of a predetermined level or higher flows, the voltage may be increased to generate a Zener voltage. Accordingly, a rising time of the switching control signal is proportional to a rising time of the Zener voltage, and internal resistance of the current source I may be improved according to the cascode connection of the current mirror unit, whereby the rising time of the Zener voltage may be controlled.

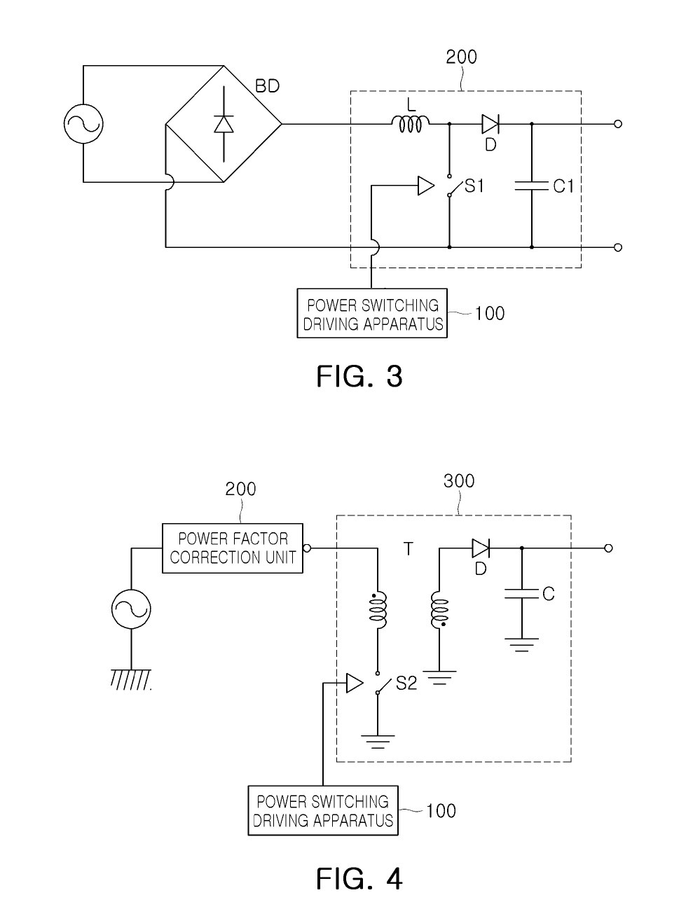

FIG. 3 is a schematic circuit diagram of a power factor correction device employing the power switching driving apparatus according to an embodiment of the present invention.

With reference to FIG. 3, the power switching driving apparatus 100 may be employed in a power factor correction device.

Namely, the power factor correction device may include the power switching driving apparatus 100 and a power factor correction unit 200. The power factor correction unit 200 may switch rectified power transferred from a bridge diode that rectifies AC power in order to adjust a phase difference between a voltage and a current to thus correct a power factor, and to this end, the power factor correction unit 200 may include an inductor L, a switching element S1, a diode D, and a capacitor C1.

The power switching driving apparatus 100 may provide a switching control signal controlling switching ON and OFF of the switching element S1.

A detailed configuration and operation of the power switching driving apparatus 100 are the same as those described above with reference to FIGS. 1 and 2, so a description thereof will be omitted.

FIG. 4 is a schematic circuit diagram of a power supply device employing the power switching driving apparatus according to an embodiment of the present invention.

With reference to FIG. 4, the power switching driving apparatus 100 may be employed in a power supply device.

Namely, the power supply device may include the power switching driving apparatus 100 and a power conversion unit 300, and may further include a power factor correction unit 200.

The power conversion unit 300 may switch input power and convert a voltage level according to a winding ratio of a transformer to supply pre-set DC power. To this end, the power conversion unit 300 may include a switching element S2, a transformer T, a diode D, and a capacitor C.

The power switching driving apparatus 100 may provide a switching control signal controlling switching ON and OFF operation of the switching element S1.

A detailed configuration and operation of the power switching driving apparatus 100 are the same as those of the foregoing description with reference to FIGS. 1 and 2, so a description thereof will be omitted. In addition, the power factor correction unit 200 may be equal to or similar to that illustrated in FIG. 3, so a description thereof will be omitted.

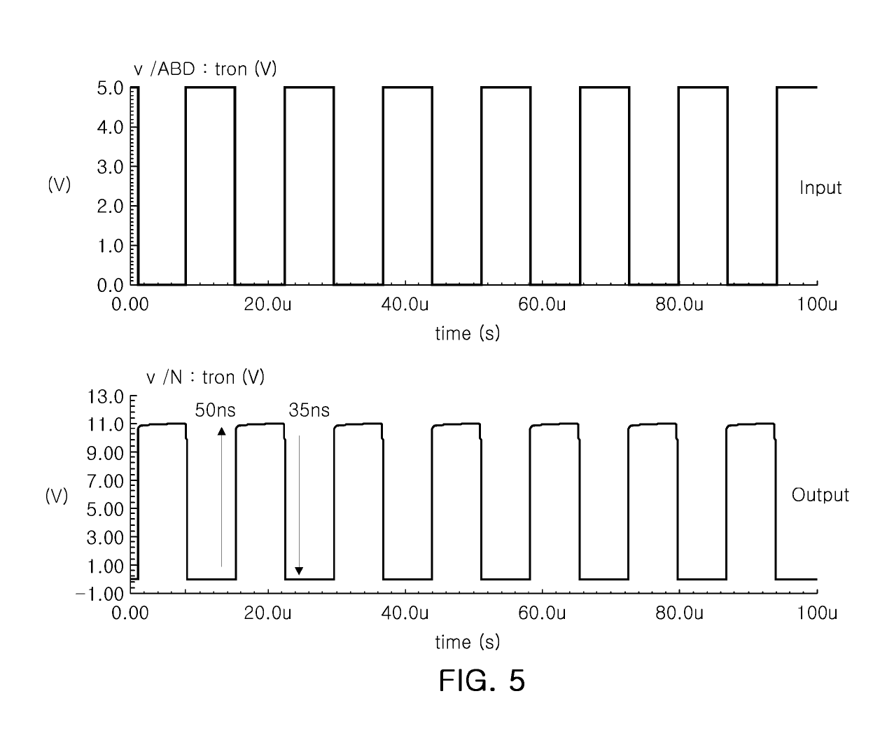

FIG. 5 is graphs showing simulation waveforms of the control signal and the switching control signal of the power switching driving apparatus according to an embodiment of the present invention.

With reference to FIG. 5, it can be seen that a high level and a low level of a switching control signal are formed such that they are complementary to a high level and a low level of the input control signal DATA and it can also be seen that a rising time and a falling time by a rising time of the Zener diode are 50 ns and 35 ns, respectively.

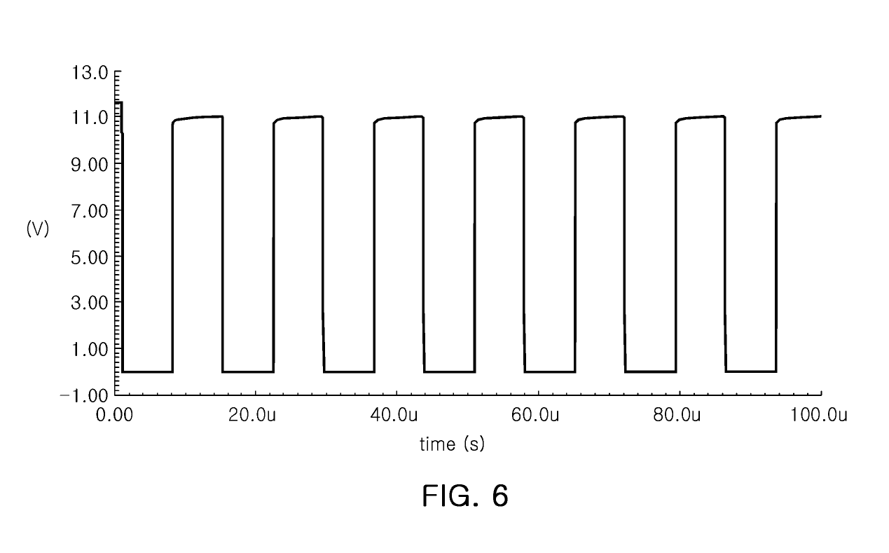

FIG. 6 is a graph showing a simulation waveform of the switching control signal over a change in the operation power (VDD) voltage of the power switching driving apparatus according to an embodiment of the present invention.

With reference to FIG. 6, it can be seen that a voltage level of the switching control signal is uniform although a voltage level of the operation power VDD of the power switching driving apparatus 100 is changed from 15V to 25V. Accordingly, a voltage between a gate and a source of the switching element may be uniform to generate a uniform drain current and stably maintain a current flowing through the inductor employed in the power factor correction device or the power supply device.

As described above, according to an embodiment of the present invention, since two NMOS transistors are cascade-connected to each other to control power switching, the circuit area may be reduced, the driving speed may be increased, and a stable switching control signal may be provided although a voltage level of the operation power VDD is changed.

As set forth above, according to the embodiments of the invention, since two NMOS transistors are cascade-connected to control power switching, the circuit area may be reduced and the driving speed may be increased.

While the present invention has been shown and described in connection with the embodiments, it will be apparent to those skilled in the art that modifications and variations can be made without departing from the spirit and scope of the invention as defined by the appended claims.

What is claimed is:

1. A power switching driving apparatus comprising:
a first driving unit providing a switching signal in response to a control signal from the outside;
a second driving unit including a first N-type channel metal oxide semiconductor field effect transistor (NMOS FET) and a second NMOS FET cascode-connected between an operational power source terminal supplying pre-set operation power and a ground, and performing switching complimentarily in response to the switching signal to provide a switching control signal controlling power switching;
a current supply unit supplying a current required for driving the second driving unit; and
a voltage maintaining unit maintaining a voltage required for driving the second driving unit.

2. The apparatus of claim 1, wherein the first driving unit includes a switching element switched according to the control signal.

3. The apparatus of claim 2, wherein the second NMOS FET is switched on and off according to switching ON and OFF operation of the switching element and the first NMOS FET is complementarily switched on and off with the second NMOS FET to provide the switching control signal.

4. The apparatus of claim 3, wherein the current supply unit includes:
a current source supplying a pre-set current; and
a current mirror unit including first and second P-type channel metal oxide semiconductor field effect transistors (PMOS FETs) cascode-connected between the operational power source terminal and the current source and third and fourth PMOS FETs connected in parallel to the first and second PMOS FETs and cascode-connected between the operational power source terminal and the second NMOS FET, and mirroring a current from the current source to the second NMOS FET.

5. The apparatus of claim 4, wherein the voltage maintaining unit includes at least one Zener diode connected between a gate of the second NMOS FET and the ground.

6. The apparatus of claim 2, wherein the switching element is a switching NMOS FET.

7. A power factor correction device comprising:
a power factor correction unit correcting a power factor by switching rectified power in response to a switching control signal; and
a power switching driving apparatus including a first driving unit providing a switching signal in response to a control signal from the outside, and a second driving unit including a first NMOS FET and a second NMOS FET cascode-connected between an operational power source terminal supplying pre-set operation power and a ground, and performing switching complimentarily according to the switching signal to provide the switching control signal.

8. The device of claim 7, wherein the power switching driving apparatus further includes:
a current supply unit supplying a current required for driving the second driving unit; and
a voltage maintaining unit maintaining a voltage required for driving the second driving unit.

9. The device of claim 8, wherein the first driving unit includes a switching element switched according to the control signal.

10. The device of claim 9, wherein the second NMOS FET is switched on and off according to switching ON and OFF operation of the switching element, and the first NMOS FET is complementarily switched on and off with the second NMOS FET to provide the switching control signal.

11. The device of claim 10, wherein the current supply unit includes:
a current source supplying a pre-set current; and
a current mirror unit including first and second PMOS FETs cascode-connected between the operational power source terminal and the current source and third and fourth PMOS FETs connected in parallel to the first and second PMOS FETs and cascode-connected between the operational power source terminal and the second NMOS FET, and mirroring a current from the current source to the second NMOS FET.

12. The device of claim 11, wherein the voltage maintaining unit includes at least one Zener diode connected between a gate of the second NMOS FET and the ground.

13. The device of claim 9, wherein the switching element is a switching NMOS FET.

14. A power supply device comprising:
a power conversion unit switching input power in response to a switching control signal to output pre-set driving power; and
a power switching driving apparatus including a first driving unit providing a switching signal in response to a control signal from the outside, and a second driving unit including a first NMOS FET and a second NMOS FET cascode-connected between an operational power source terminal supplying pre-set operation power and a ground and performing switching complimentarily according to the switching signal to provide the switching control signal.

15. The device of claim 14, wherein the power switching driving apparatus further includes:
a current supply unit supplying a current required for driving the second driving unit; and
a voltage maintaining unit maintaining a voltage required for driving the second driving unit.

16. The device of claim 15, wherein the first driving unit includes a switching element switched according to the control signal.

17. The device of claim 16, wherein the second NMOS FET is switched on and off according to switching ON and OFF operation of the switching element, and the first NMOS FET is complementarily switched on and off with the second NMOS FET to provide the switching control signal.

18. The device of claim 17, wherein the current supply unit includes:
a current source supplying a pre-set current; and
a current mirror unit including first and second PMOS FETs cascode-connected between the operational power source terminal and the current source and third and fourth PMOS FETs connected in parallel to the first and second PMOS FETs and cascode-connected between the operational power source terminal and the second NMOS FET, and mirroring a current from the current source to the second NMOS FET.

19. The device of claim 18, wherein the voltage maintaining unit includes at least one Zener diode connected between a gate of the second NMOS FET and the ground.

20. The device of claim 14, further comprising a power factor correction unit switching rectified power, correcting a power factor thereof, and providing the same to the power conversion unit.

21. The device of claim 16, wherein the switching element is a switching NMOS FET.
